(19) United States
(12) Patent Application Publication
(10) Pub. No.: US 2021/0035898 A1
(43) Pub. Date: Feb. 4, 2021

(54) PACKAGE STRUCTURE AND MANUFACTURING METHOD THEREOF

(71) Applicant: Powertech Technology Inc., Hsinchu County (TW)

(72) Inventor: Yutaka Kagaya, Hsinchu County (TW)

(73) Assignee: Powertech Technology Inc., Hsinchu County (TW)

(21) Appl. No.: 16/525,608

(22) Filed: Jul. 30, 2019

(51) Int. Cl. H01L 23/498; H01L 23/31; H01L 23/367; H01L 23/00; H01L 21/48; H01L 21/56; H01L 21/78

(52) U.S. Cl. CPC H01L 23/49838; H01L 23/3128; H01L 23/3672; H01L 23/49816; H01L 24/48; H01L 24/16; H01L 2224/16227; H01L 21/4867; H01L 21/565; H01L 21/561; H01L 21/78; H01L 2224/48227; H01L 21/4853

(57) ABSTRACT

A package structure and a manufacturing method thereof are provided. The package structure includes a substrate having a first surface and a second surface opposite to each other, a die electrically coupled to the substrate, an encapsulant disposed over the first surface of the substrate to encapsulate the die, at least one first conductive terminal and at least one second conductive terminal. The at least one first conductive terminal and the at least one second conductive terminal are disposed on the second surface of the substrate. The at least one second conductive terminal is electrically connected to the die through the substrate. The at least one first conductive terminal is overlapped with the die in a direction perpendicular to the second surface of the substrate. A first area of the at least one first conductive terminal is larger than a second area of the at least one second conductive terminal.

### BACKGROUND

### Technical Field

The disclosure generally relates to a package structure and a manufacturing method thereof, and in particular, to a package structure having different solder areas and a manufacturing method thereof.

### Description of Related Art

In a ball grid array (BGA) package, a die is mounted on a package substrate and an array of solder balls are provided on the package substrate at a side opposite to the die. In a conventional BGA package, the pitches and sizes of the solder balls are the same in the die region and the peripheral region. With the rapid development of semiconductor packaging technology, how to improve the heat dissipation performance of the package structure has become a challenge in the field.

### SUMMARY

The disclosure provides a package structure and a manufacturing method thereof, which effectively improve the heat dissipation performance of the package structure.

The disclosure provides a package structure including a substrate, a die, an encapsulant, at least one first conductive terminal and at least one second conductive terminal. The substrate has a first surface and a second surface opposite to each other. The die is electrically coupled to the substrate. The encapsulant is disposed over the first surface of the substrate to encapsulate the die. The at least one first conductive terminal and the at least one second conductive terminal are disposed on the second surface of the substrate, and the at least one second conductive terminals is electrically connected to the die through the substrate. The at least one first conductive terminal is overlapped with the die in a direction perpendicular to the second surface of the substrate. A first area of the at least one first conductive terminal is larger than a second area of the at least one second conductive terminal.

The disclosure provides a manufacturing method of a package structure. The method includes at least the following processes. A substrate is provided. The substrate has a first surface and a second surface opposite to each other. The substrate also has a die region and a peripheral region surrounding the die region. A die is mounted on the first surface within the die region of the substrate. An encapsulant is formed over the first surface of the substrate to encapsulate the die. At least one first conductive terminal is formed on the second surface within the die region of the substrate such that the at least one first conductive terminal is overlapped with the die in a direction perpendicular to the second surface of the substrate. At least one second conductive terminal is formed on the second surface within the peripheral region of the substrate. The at least one first conductive terminal and the at least one second conductive terminal are electrically connected to the die through the substrate. A first area of the at least one first conductive terminal is larger than a second area of the at least one second conductive terminal.

In view of above, the first conductive terminal is formed to have a larger area than the second conductive terminal, and the first conductive terminal is overlapped with the die in a direction perpendicular to the surface of the substrate. With such configuration, the heat originated from the die may be dissipated through the substrate and the first and second conductive terminals disposed thereon in a faster rate. As a result, the heat dissipation performance of the package structure may be greatly improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 8A are top views or bottom views illustrating a manufacturing method of a package structure according to some embodiments of the disclosure.

FIG. 1B to FIG. 8B are cross-sectional views taken along I-I′ line of FIG. 1A to FIG. 8A.

FIG. 9A to FIG. 9D are bottom views of various package structures according to some alternative embodiments of the disclosure.

FIG. 10A and FIG. 10B are cross-sectional views of various package structures according to some alternative embodiments of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

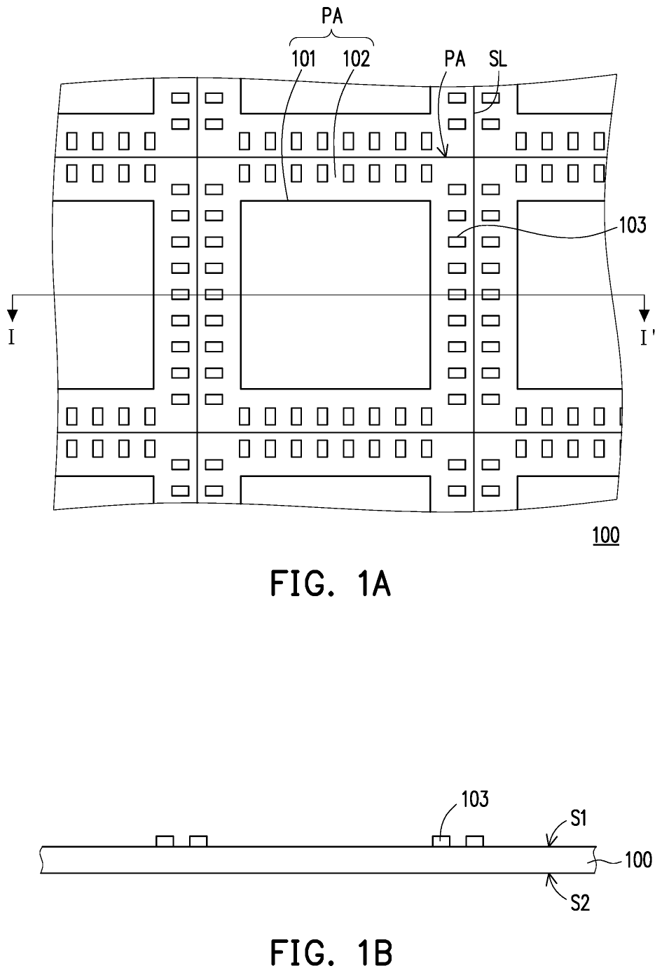

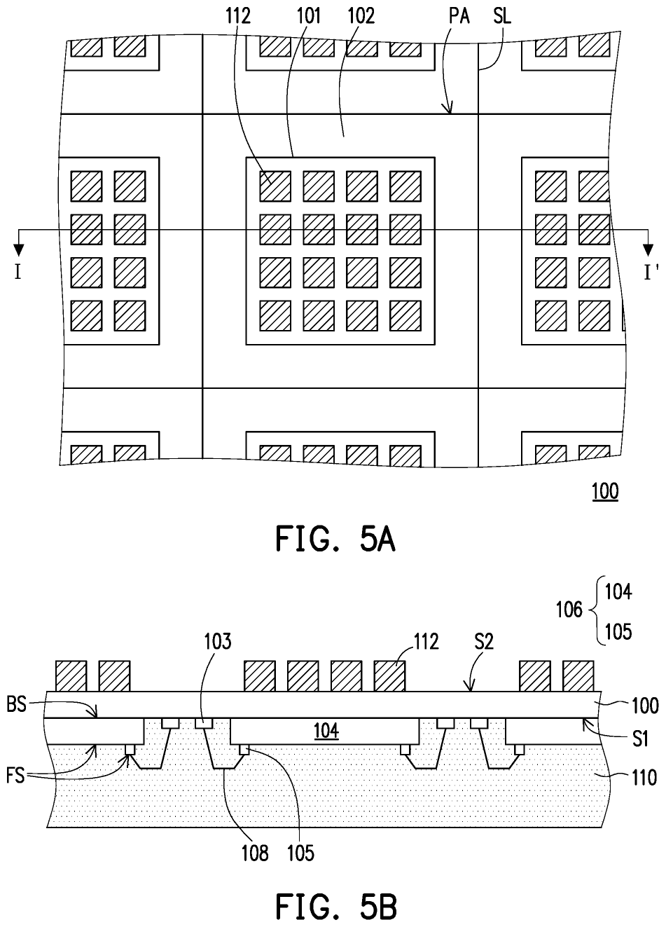

FIG. 1A to FIG. 8A are top views or bottom views illustrating a manufacturing method of a package structure 200a according to some embodiments of the disclosure. FIG. 1B to FIG. 8B are cross-sectional views taken along I-I′ line of FIG. 1A to FIG. 8A. It should be noted that FIG. 1A to FIG. 4A illustrate top views of the package structure 200a while FIG. 5A to FIG. 8A illustrate bottom views of the package structure 200a.

Referring to FIG. 1A and FIG. 1B, a substrate 100 is provided. In some embodiments, the substrate 100 is a circuit board substrate or a redistribution layer (RDL) structure. For example, the substrate 100 may be formed by stacking dielectric layers and conductive patterns alternately. The dielectric layers may include a core dielectric layer, a polymer material such as polyimide (PI), polybenzoxazole (PBO), benzocyclobutene (BCB), or a combination thereof. The conductive patterns include copper, aluminum, or other suitable metallic materials or combinations thereof. The conductive patterns are interconnected to each other by conductive vias penetrating through the dielectric layers. In some embodiments, the conductive patterns are disposed in and/or on the dielectric layers. In some embodiments, the substrate 100 includes a plurality of package regions PA separated from each other by scribe lines SL. Each package region PA includes a die region 101 and a peripheral region 102 surrounding the die region 101. The die region 101 refers to a region on which a die is to be mounted.

The substrate 100 has a first surface S1 and a second surface S2 opposite to each other. In some embodiments, the substrate 100 has a plurality of connectors 103 on the first surface S1 of the substrate 100. The connectors 103 include conductive materials such as metal or metal alloy. For example, the connectors 103 may include copper, aluminum, alloys thereof, or combinations thereof. In some embodiments, the connectors 103 are referred to as “bond fingers” or “conductive pads”. As illustrated in FIG. 1A, the connectors 103 are disposed in the peripheral region 102, but the disclosure is not limited thereto. In some alternative embodiments, the connectors 103 may be disposed in the die region 101 or in both of the peripheral region 102 and the die region 101.

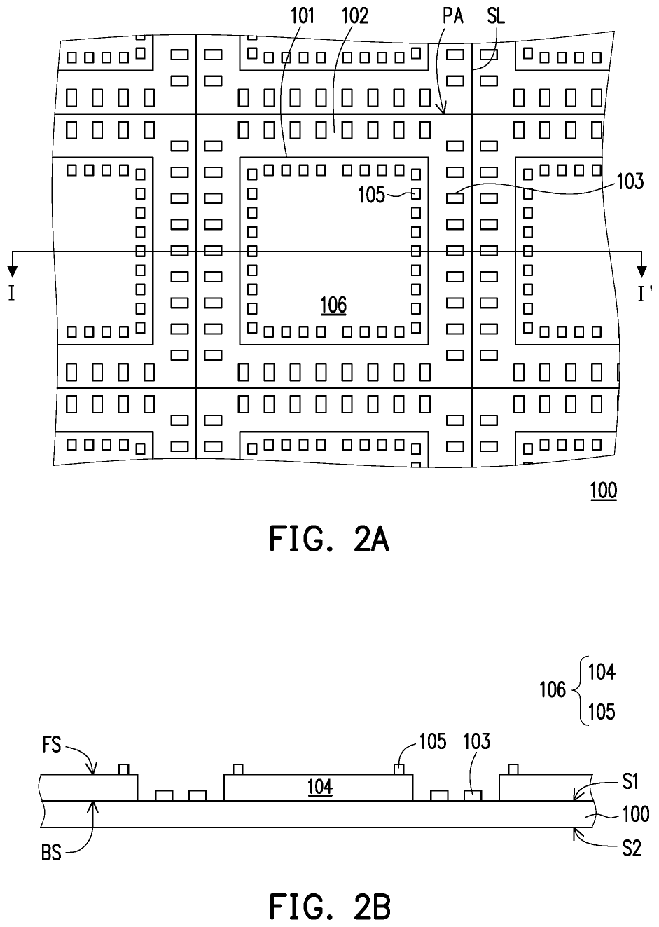

Referring to FIG. 2A and FIG. 2B, a plurality of dies 106 is mounted on the first surface S1 of the substrate 100. As illustrated in FIG. 2A, the dies 106 are disposed within the die region 101. The dies 106 may include digital dies, analog dies, or mixed signal dies. For example, the dies 106 may be application-specific integrated circuit (ASIC) dies, logic dies, or other suitable dies. In some embodiments, each die 106 includes a substrate 104 and a plurality of conductive pads 105 on the substrate 104. In some embodiments, the substrate 104 is a semiconductor substrate. For example, the substrate 104 may be a silicon substrate. In some embodiments, a plurality of active devices (such as transistors or the like), a plurality of passive devices (such as resistors, capacitors, inductors, or the like) or combinations thereof may be formed in and/or on the substrate 104. In addition, an interconnection structure may be formed in substrate to electrically connect the active devices, the passive devices, and the conductive pads 105. The interconnection structure may include a plurality of dielectric layer and conductive features formed in the dielectric layers. In some embodiments, the conductive pads 105 are electrically connected to a top conductive feature of the interconnection structure, so electrical connection between the active devices, the passive devices, and the conductive pads 105 may be realized.

The material of the conductive pads 105 may include metal or metal alloy, such as aluminum, copper, nickel, or alloys thereof. In some embodiments, at least a portion of each conductive pad 105 is exposed to serve as external connections of the die 106. The conductive pads 105 may protrude from the top surface of the die 106, but the disclosure is not limited thereto. In some other embodiments, the top surfaces of the conductive pads 105 may be coplanar with or lower than the top surface of the die 106.

As illustrated in FIG. 2A and FIG. 2B, the die 106 has a front surface FS and a back surface BS opposite to each other. The conductive pads 105 are located on the front surface FS, so the front surface FS may be referred to as an active surface of the die 106. As illustrated in FIG. 2B, the die 106 is mounted over the substrate 100 with the back surface 104 attached to the first surface S1 of the substrate 100. The back surface BS of the die 106 may be attached to the first surface 100 through an adhesive film (not shown), such as a die attach film. However, the disclosure is not limited thereto. In some alternative embodiments, the die 106 may be mounted on the substrate 100 in a flip-chip manner. That is, the die 106 may be bonded on the substrate 100 such that the front surface FS of the die 106 faces the first surface S1 of the substrate 100.

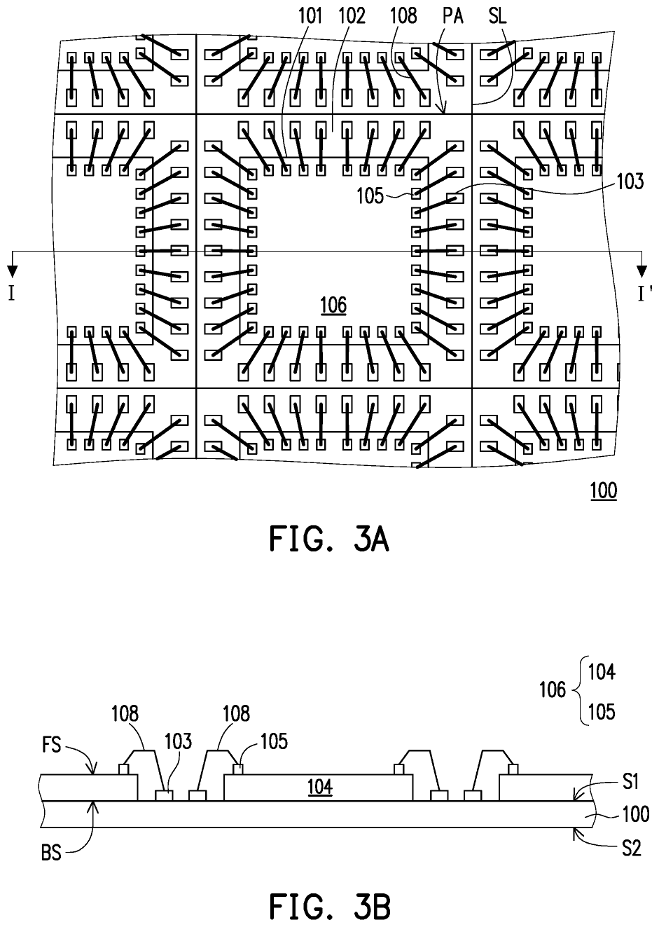

Referring to FIG. 3A and FIG. 3B, a plurality of conductive wires 108 are formed to electrically connect the die 106 and the substrate 100. In some embodiments, one end of the conductive wire 108 is connected to the conductive pad 105 of the die 106 and another end of the conductive wire 108 is connected to the connector 103 of the substrate 100. A material of the conductive wires 108 may include gold, aluminum, or other suitable conductive materials. The conductive wire 108 may be formed by a wire bonding process, a thermosonic bonding process, or the like.

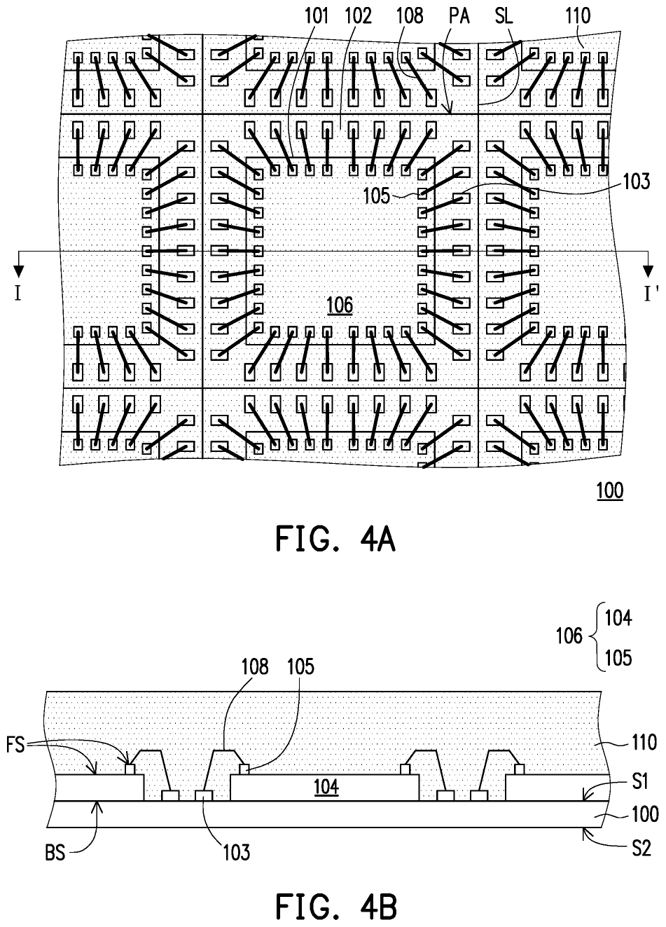

Referring to FIG. 4A and FIG. 4B, an encapsulant 110 is formed over the substrate 100 to encapsulate the dies 106 and the conductive wires 108. The encapsulant 110 may include a molding compound or an insulating material such as epoxy, silicone, or other suitable resins. The encapsulant 110 may be formed by a molding process. In some embodiments, a top surface of the encapsulant 110 is located at a level height higher than that of a top surface (such as the front surfaces FS) of the die 106. As illustrated in FIG. 4B, the encapsulant 110 encapsulates the top surfaces and sidewalls of the dies 106 and the conductive wires 108. In other words, the dies 106 and the conductive wires 108 are embedded in the encapsulant 110.

Referring to FIG. 5A and FIG. 5B, the structure of FIG. 4A and FIG. 4B is flipped upside down such that the second surface S2 of the substrate 100 faces upward. A plurality of first conductive terminals 112 is then formed on the second surface S2 of the substrate 100. In some embodiments, the first conductive terminals 112 are formed on the conductive pads (not shown) of the substrate 100. The first conductive terminals 112 are electrically connected to the substrate 100 and are further electrically coupled to the dies 106 through the conductive patterns and the conductive vias embedded in the substrate 100. In some embodiments, the first conductive terminals 112 may be ground connectors, power connectors, or a combination thereof.

In some embodiments, the first conductive terminals 112 are formed within the die region 101 of the substrate 100 directly over the dies 106. In other words, the first conductive terminals 112 are overlapped with the die 106 in a direction perpendicular to the second surface S2 or the first surface S1 of the substrate 100.

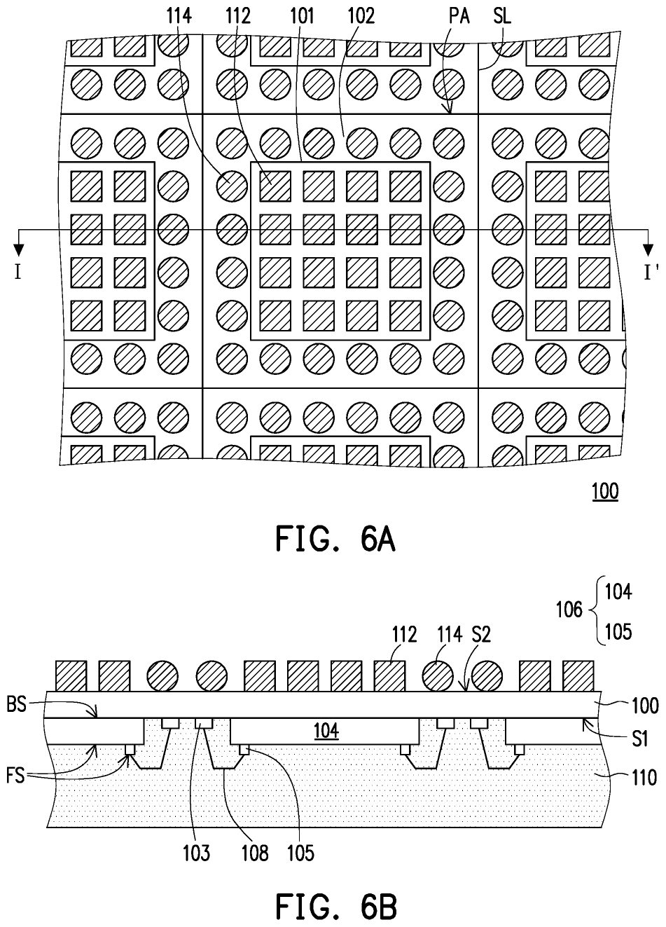

In some embodiments, the first conductive terminals 112 are solder pastes formed by a solder paste printing process. The solder paste may include a mixture of a flux and solder powder, or the like. The solder powder may include tin, silver, copper, bismuth, lead, alloys thereof, or combinations thereof. In some embodiments, the solder paste printing process includes the following steps. First, a first stencil (not shown) having openings correspond to the conductive pads located in the die region 101 of the substrate 100 is placed on the second surface S2 of the substrate 100. A solder paste is then applied/printed on the conductive pads exposed by the openings of the first stencil. Thereafter, the first stencil is removed and a reflow process is performed on the solder paste to enhance the attachment between the solder paste and the conductive pads of the substrate 100. After the reflow process, the first conductive terminals 112 are formed on the second surface S2 of the substrate 100. In some embodiments, the shape of the first conductive terminal 112 from the cross-sectional view and/or the top or bottom view may be square, rounded square, rectangle, rounded rectangle, the like, or other suitable shape. Also, the forming step of the first conductive terminals 112 is preferably performed before the forming step of the second conductive terminals 114 (shown in FIGS. 5A-6A and 5B-6B) due to the need for setting the first stencil on the second surface S2 of the substrate 100 by solder paste printing.

Referring to FIG. 6A and FIG. 6B, a plurality of second conductive terminals 114 is formed on the second surface S2 of the substrate 100 within the peripheral region 102. The second conductive terminal 114 may include a material similar to or different from the material of the first conductive terminal 112. In some embodiments, the second conductive terminals 114 may be formed by a process different from that of the first conductive terminal 112. The second conductive terminals 114 may be spherical conductive balls, such as solder balls. In some embodiments, the second conductive terminals 104 may be formed by a solder ball placement process. In some embodiments, the solder ball placement process includes the following steps. First, a second stencil (not shown) having openings correspond to the conductive pads located in the peripheral region 102 of the substrate 100 is placed over the second surface S2 of the substrate 100. Subsequently, a layer of flux is applied/printed on the conductive pads exposed by the openings of the second stencil. Thereafter, conductive balls (for example, solder balls, gold balls, copper balls, nickel balls, or the like) are dispersed over the second stencil and are driven into the openings of the second stencil. Upon falling into the openings of the second stencil, the conductive balls are attached to the flux located in the openings. Afterwards, the second stencil is removed and a reflow process is performed to enhance the attachment between the conductive balls and the flux and between the flux and the conductive pads of the substrate 100. After the reflow process, the second conductive terminals 114 are formed on the second surface S2 of the substrate 100. In some embodiments, as described above, two reflow processes are separately performed for forming the first conductive terminals 112 and the second conductive terminals 114, but the disclosure is not limited thereto. In some alternative embodiments, the reflow process may be performed after forming both of the solder paste for the first conductive terminals 112 and the conductive balls for the second conductive terminals 114. As illustrated in FIG. 6A, within each package region PA, the second conductive terminals 114 surround the first conductive terminals 112. In some embodiments, the second conductive terminals 114 may be used for performing functions the same as or different from those of the first conductive terminals 112.

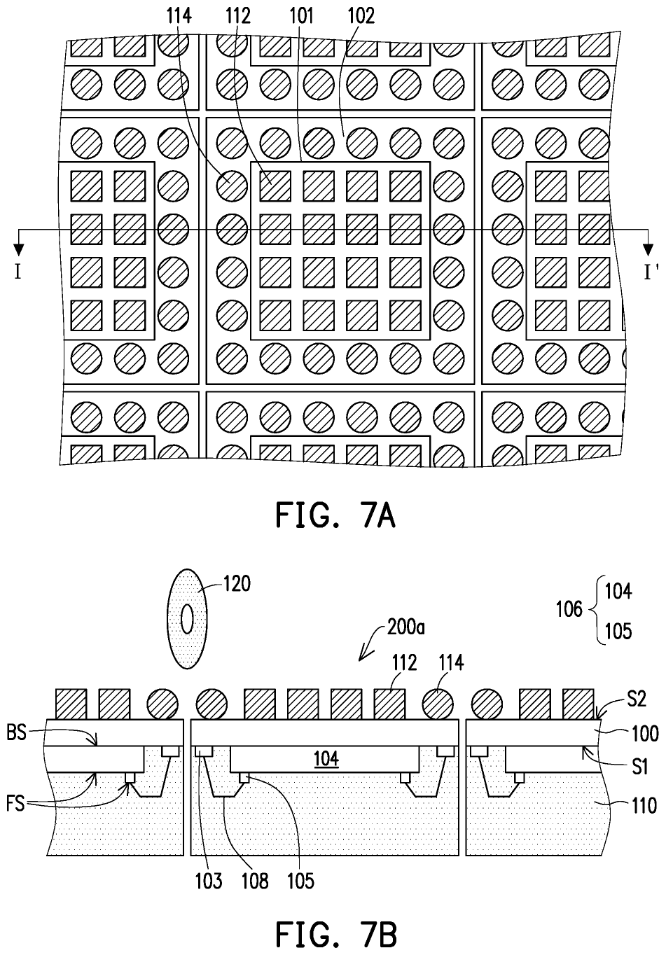

Referring to FIG. 7A and FIG. 7B, a singulation process is performed along the scribe lines SL, so as to form a plurality of package structures 200a. The singulation process may include a mechanical dicing process using a blade 120. Alternatively, the singulation process may include a laser dicing process, a plasma dicing process, or a combination thereof.

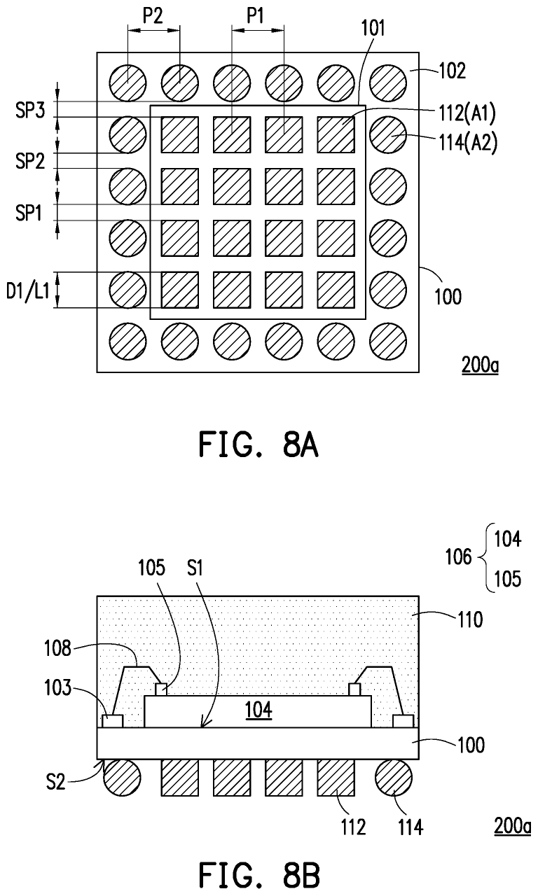

Referring to FIG. 8A and FIG. 8B, the package structure 200a includes the substrate 100, the die 106, the encapsulant 110, the first conductive terminals 112 and the second conductive terminals 114. The die 106 is disposed on the first surface S1 of the substrate 100. The first conductive terminals 112 and the second conductive terminals 114 are disposed on the second surface S2 of the substrate 100. The first conductive terminals 112 and the second conductive terminals 114 are separated from each other and are electrically connected to the die 106 through the substrate 100.

In some embodiments, the first conductive terminals 112 are located within the die region 101 of the substrate 100. In other words, the first conductive terminals 112 are overlapped with the die 106 in a direction perpendicular to the first surface S1 or the second surface S2 of the substrate 100. The second conductive terminals 114 are located within the peripheral region 102 of the substrate 100. In other words, the second conductive terminals 114 surround the first conductive terminals 112. In some embodiments, the sidewalls of the first conductive terminals 112 closest to the edge of the die region 106 may be aligned with or laterally offset from the sidewalls of the die 106. It should be understood that, the number of the first conductive terminals 112 and the second conductive terminal 114 shown in the figures are merely exemplary illustration, and the disclosure is not limited thereto.

As illustrated in FIG. 8A and FIG. 8B, all of the first conductive terminals 112 have the same shape and size. Similarly, all of the second conductive terminals 114 have the same shape and size. On the other hand, the shape and size of the first conductive terminals 112 are different from those of the second conductive terminals 114. For example, the shape of each first conductive terminal 101 may be square, rectangular, or the like. The shape of each second conductive terminal 114 may be circular, elliptical, or the like. It is noted that the shapes and sizes of the first and second conductive terminals 112 and 114 discussed herein refer to the shapes and size of the first and second conductive terminals 112 and 114 orthogonally projected onto the second surface S2 of the substrate 100 (i.e. viewed in a bottom view).

As illustrated in FIG. 8A, the size (e.g. an area) of each of the first conductive terminals 112 is larger than the size (e.g. an area) of each of the second conductive terminals 114. For example, the ratio of the area A1 of each of the first conductive terminals 112 to the area A2 of each of the second conductive terminals 114 is larger than 1. For example, the ratio may be 2 or greater. In some embodiments, each of the first conductive terminals 112 has an area larger than each of the second conductive terminal 114, and a total area of the first conductive terminals 112 within the die region 101 is also larger than a total area of the second conductive terminals 114 in the peripheral region 102.

As illustrated in FIG. 8A, a length L1 of a side of each of the first conductive terminals 112 may be equal to a diameter D1 of each of the second conductive terminals 114. In some embodiments, a pitch P1 between two adjacent first conductive terminals 112 is equal to a pitch P2 between two adjacent second conductive terminals 114. The term “pitch” described herein refers to the distance from a center of the feature to a center of next immediately adjacent feature. In some embodiments, a spacing SP1 between two adjacent first conductive terminals 112 is equal to a spacing SP2 between two adjacent second conductive terminals 114. In some embodiments, a spacing SP3 between the adjacent first conductive terminal 112 and the second conductive terminal 114 may be equal to the spacing SP1 and the spacing SP2. However, the disclosure is not limited thereto. The spacing between different conductive terminals may be the same as or different from each other, as long as the spacing is large enough for the process window.

In some embodiments, the solder regions may assist the conduction of heat (mostly generated from the die) away from the package structure. In other words, the heat dissipation performance of a device is related to the area of the solder region. As illustrated in FIG. 8A and FIG. 8B, since the first conductive terminals 112 directly underneath the die 106 are formed to have a larger area than the second conductive terminals 114 not directly underneath the die 106, the heat generated by the die 106 may be effectively dissipated through the first conductive terminals 112, thereby enhancing the heat dissipation performance of the package structure 200a. In addition, since the spacing or pitches between the conductive terminals are kept the same, the process window is not affected and the simplicity in the manufacturing process is maintained.

As illustrated in FIG. 8A and FIG. 8B, all of the first conductive terminals 112 have the same shape and size. However, the disclosure is not limited thereto. Other configurations of the first conductive terminals 112 will be described below.

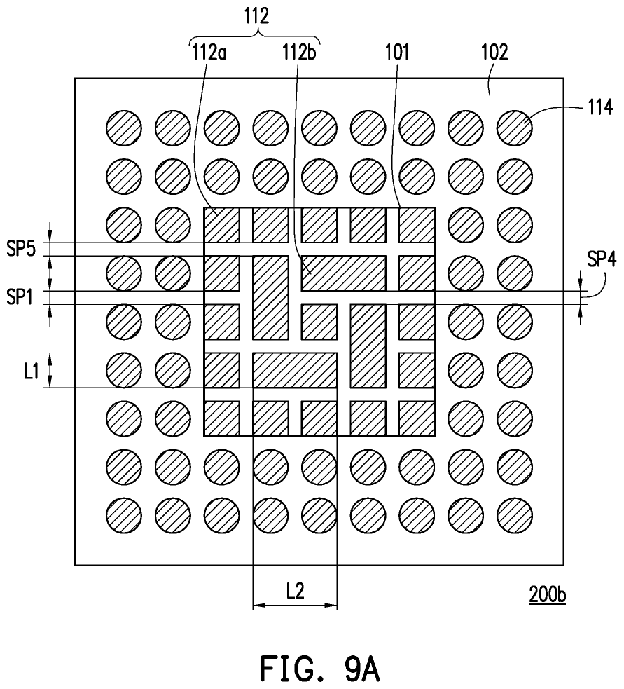

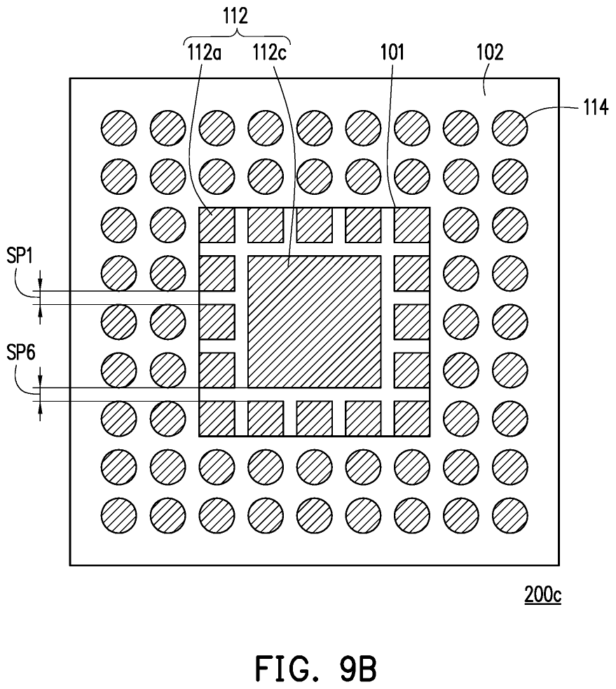

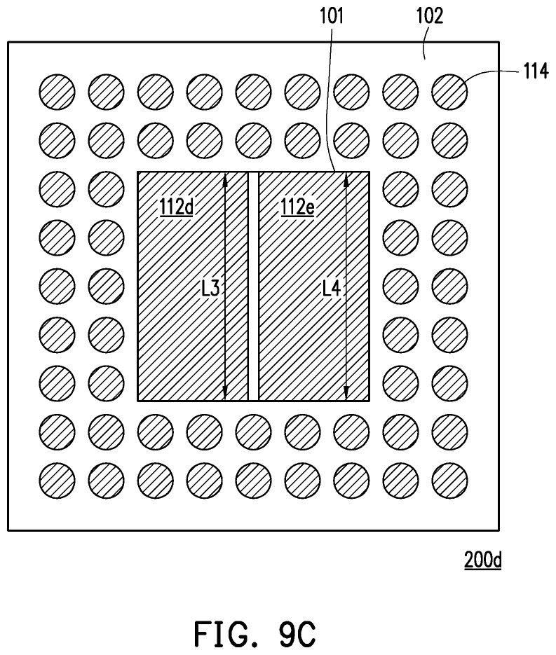

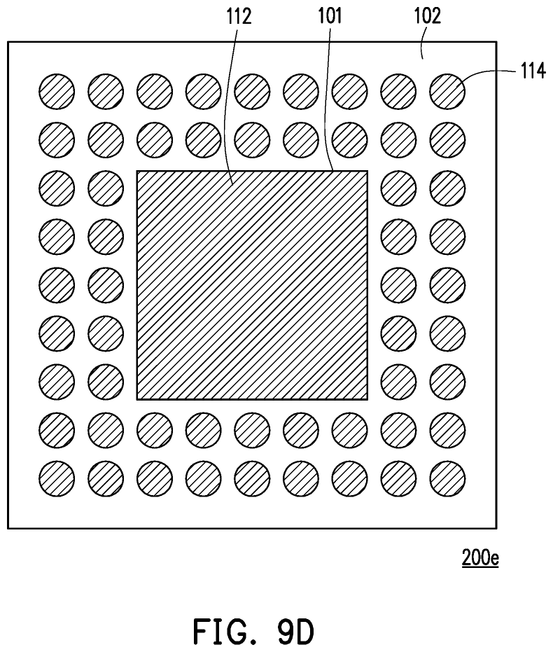

FIG. 9A to FIG. 9D are bottom views of various package structures 200b-200e according to some alternative embodiments of the disclosure. The relative positions of the first conductive terminals 112 and the second conductive terminals 114 in FIGS. 9A to 9D are substantially the same as those described in FIG. 8A, so the detailed descriptions thereof are omitted herein.

Referring to FIG. 9A, a bottom view of the package structure 200b is shown. In the package structure 200b, the first conductive terminals 112 are divided into first conductive terminals 112a and first conductive terminals 112b. The first conductive terminal 112a and the first conductive terminal 112b have different shapes and different sizes. For example, each first conductive terminal 112a is square while each first conductive terminal 112b is rectangular. Each of the first conductive terminal 112b has an area larger than an area of each first conductive terminal 112a. On the other hand, each of the first conductive terminals 112a and 112b has an area larger than the area of each of the second conductive terminals 114.

In some embodiments, each first conductive terminal 112b has two short sides connecting two long sides. Each short side has a length L1 and each long side has a length L2. On the other hand, since the first conductive terminals 112b are squares, each first conductive terminal 112a has four sides with equal length L1. In some embodiments, the length L1 of the short side of the first conductive terminal 112b may be equal to the length L1 of each side of the first conductive terminal 112a. In some embodiments, even though the first conductive terminals 112 have different shapes and sizes, the spacing between adjacent first conductive terminals are kept the same. For example, as illustrated in FIG. 9A, a spacing SP1 between two adjacent first conductive terminals 112a, a spacing SP4 between two adjacent first conductive terminals 112b, and a spacing SP5 between adjacent first conductive terminal 112a and first conductive terminal 112b are the same. However, the disclosure is not limited thereto. The spacing between different conductive terminals may be the same as or different from each other, as long as the spacing is larger enough for the process window.

Referring to FIG. 9B, a bottom view of the package structure 200c is shown. In the package structure 200c, the first conductive terminals 112 are divided into first conductive terminals 112a and a first conductive terminal 112c. In some embodiments, the first conductive terminal 112c and the first conductive terminal 112a have the same shape. However, a size (an area) of the first conductive terminal 112c is larger than a size (an area) of each of the first conductive terminal 112a. For example, the first conductive terminals 112a and 112c are all square. In some embodiments, the first conductive terminal 112c is a single larger solder region surrounded by multiple smaller first conductive terminals 112a. In some embodiments, the spacing SP6 between the adjacent first conductive terminal 112a and the first conductive terminal 112c is equal to the spacing SP1 between two adjacent first conductive terminals 112a.

Referring to FIG. 9C, a bottom view of the package structure 200d is shown. In the package structure 200d, the first conductive terminals 112 is divided into a first conductive terminal 112d and a first conductive terminal 112e having the same shape and size. For example, both of the first conductive terminal 112d and the first conductive terminal 112e are rectangular. In some embodiments, a long side of the first conductive terminal 112d has a length L3, a long side of the first conductive terminal 112e has a length L4, and the length L3 of the first conductive terminal 112d and the length L4 of the second conductive terminal 112e may be equal to each other. In some embodiments, the length L3 and the length L4 may be equal to or slightly less than the length of the die region 101. The first conductive terminals 112d and 112e are spaced apart from each other. In some embodiments, the first conductive terminal 112d and the first conductive terminal 112e may perform different functions. For example, the first conductive terminal 112d may be a ground connector which is electrically grounded. For example, the first conductive terminal 112d is connected to a ground pad of the die 106 through the substrate 100. The first conductive terminal 112e may be a power connector which is connected to a power pad (i.e. power input/output (I/O)) of the die 106 through the substrate 100.

Referring to FIG. 9D, a bottom view of the package structure 200e is shown. In the package structure 200e, the first conductive terminal 112 is a single large solder paste disposed in the die region 101. An area of the first conductive terminal 112 may be substantially the same as or less than an area of the die region 101. In some embodiments, the first conductive terminal 112 is a ground connector, but the disclosure is not limited thereto. In some embodiment, the first conductive terminal 112 may be a non-connect pin. However, the first conductive terminal 112 is preferably electrically connected to a power supply pin or a ground pin, in order to facilitate platting to the substrate.

As illustrated in FIG. 8A to FIG. 8B and FIG. 9A to FIG. 9D, the first conductive terminals 112 are completely located within the die region 101 and are overlapped with the die 106 in a direction perpendicular to the first surface S1 or the second surface S2 of the substrate 100, and the second conductive terminals 114 are completely located within the peripheral region 102 and are not overlapped with the die 106 in the direction perpendicular to the first surface S1 or the second surface S2 of the substrate 100. However, the disclosure is not limited thereto. In some alternative embodiments, portions of the first conductive terminals 112 may extend from the die region 101 to the peripheral region 102 or portions of the second conductive terminals 114 may extend from the peripheral region 102 to the die region 101.

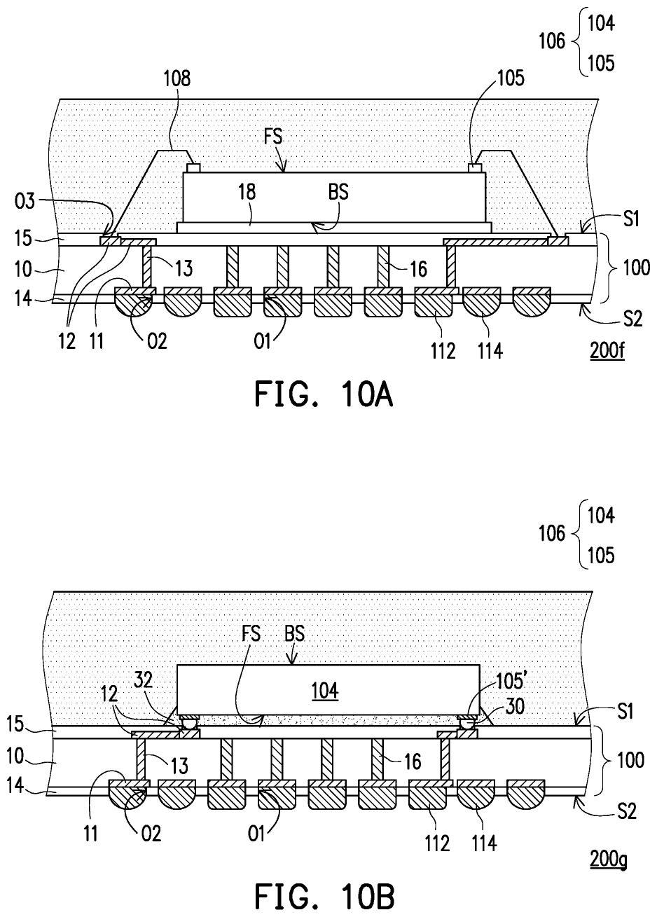

FIG. 10A and FIG. 10B are cross-sectional views of various package structures 200f-200g according to some alternative embodiments of the disclosure.

Referring to FIG. 10A, a cross-sectional view of the package structure 200f is shown. The package structure 200f in FIG. 10A is similar to the package structure 200a in FIG. 8A, so similar components are denoted by the same reference numeral and the detailed descriptions thereof are omitted herein. As illustrated in FIG. 10A, the substrate 100 includes a dielectric body 10, conductive layers 11 and 12, a plurality of through vias 13, and protection layers 14 and 15. The conductive layer 11 and the conductive layer 12 are disposed on opposite surfaces of the dielectric body 10, and may be embedded in or protrude from the corresponding surface of the dielectric body 10, respectively. For example, the conductive layer 11 is embedded in and partially exposed by the dielectric body 10. In some embodiments, the bottom surface of the conductive layer 11 is substantially coplanar with the bottom surface of the dielectric body 10. The conductive layer 12 is disposed on and protruding from the top surface of the dielectric body 10.

The through vias 13 are embedded in and penetrating through the dielectric body 10, so as to electrically connect the conductive layer 11 and the conductive layer 12. The number of the through vias 13 shown in FIG. 10A is merely an exemplary illustration, and the disclosure is not limited thereto. In some alternative embodiments, more through vias 13 or less through vias 13 may be embedded in the dielectric body 10. In some embodiments, the protection layers 14 and 15 are disposed on opposite surfaces of the dielectric body 10 to respectively cover portions of the conductive layers 11 and 12. A material of the protection layers 14 and 15 includes, for example, solder resist.

In some embodiments, at least a portion of the conductive layers 11 is exposed by the protection layer 14 at the second surface S2 of the substrate. Similarly, at least a portion of the conductive layer 12 is exposed by the protection layer 15 at the first surface S1 of the substrate 100. For example, the protection layer 14 is disposed on and covers the bottom surface of the dielectric body 10 such that portions of the bottom surfaces of the conductive layers 11 are also covered by the protection layer 14. In some embodiments, the protection layer 14 has a plurality of openings O1 and O2 exposing portions of the bottom surfaces of the conductive layers 11. The protection layer 15 is disposed on and covers the top surface of the dielectric body 10 such that sidewalls and portions of the top surfaces of the conductive layers 12 are also covered by the protection layer 15. In some embodiments, the top surface of the protection layer 15 is located at a level height higher than the top surface of the conductive layers 12. In some embodiments, the protection layer 15 has openings O3 exposing portions of the top surfaces of the conductive layers 15.

As illustrated in FIG. 10A, the die 106 is attached to the first surface S1 of the substrate 100 through an adhesive layer 18. In some embodiments, the sidewalls of adhesive layer 18 laterally protrude from the sidewalls of the die 106, but the disclosure is not limited thereto. In some alternative embodiments, the sidewalls of the adhesive layer 18 may be aligned with the sidewalls of the die 106. The conductive wires 108 electrically connect the conductive pads 105 of the die 106 and the conductive layers 12 exposed by the openings 03 of the protection layer 15. It is understood that, the exposed conductive layers 12 shown in FIG. 10A are examples of the connectors 103 shown in FIGS. 1A and 1B.

In some embodiments, the first conductive terminals 112 are formed on and in physical contact with the conductive layer 11 exposed by the openings O1 of the protection layer 14. On the other hand, the second conductive terminals 114 are formed on and in physical contact with the conductive layers 11 exposed by the openings O2 of the protection layer 14. In some embodiments, the top surfaces of the first conductive terminals 112 and the second conductive terminals 114 are substantially coplanar with each other. The bottom surface of the first conductive terminals 112 and the second conductive terminals 114 may be substantially coplanar with each other or locate at different level heights. In some embodiments, the heights of the first conductive terminals 112 and the second conductive terminals 114 in the direction perpendicular to the second surface S2 of the substrate 100 may be substantially the same as or different from each other. The shapes of the first conductive terminals 112 and the second conductive terminals 114 may be configured depending on the shapes of the corresponding conductive layers 11 exposed by the openings O1 and O2. In other words, the shapes of the first conductive terminals 112 are defined by the shapes of the corresponding openings O1 while the shapes of the second conductive terminals 114 are defined by the shapes of the corresponding openings O2. In some embodiments, the openings O1 and the openings O2 are formed to have different shapes. For example, the shapes of the openings O1 may be square, rectangular, irregular, or the like and the shapes of the openings O2 may be circular, elliptical, or the like. In some embodiments, an area of each opening O1 is larger than an area of each opening O2. The shapes of the opening O1 and O2 described herein refer to the shapes thereof in a plane along the second surface S2 of the substrate 100. Moreover, in some embodiments, a plurality of heat dissipation through vias 16 is embedded in the substrate 100. For example, each of the heat dissipation through vias 16 is vertically aligned with an associated one of the first conductive terminal 112, so as to increase the heat dissipation performance. As illustrated in FIG. 10A, the heat dissipation through vias 16 may be electrically isolated from the die 106, but the disclosure is not limited thereto. In some alternative embodiments, the heat dissipation through vias 16 may be electrically connected to the die 106. It is noted that, the heat dissipation through vias 16 are optionally provided in the substrate 100, and the substrate 100 may be free of the heat dissipation through vias in some other embodiments.

Referring to FIG. 10B, a cross-sectional view of the package structure 200g is shown. The package structure 200g in FIG. 10B is similar to the package structure 200f in FIG. 10A, so similar components are denoted by the same reference numeral and the detailed descriptions thereof are omitted herein. The package structure 200g of FIG. 10B differs from the package structure 200f of FIG. 10A in that the die 106 is bonded to the substrate 100 in a flip-chip manner.

As illustrated in FIG. 10B, the die 106 is boned to the substrate 100 with the front surface FS facing the substrate 100. For example, a plurality of connectors 105′ are formed on the front surface FS of the die 106. The connector 105′ includes solder bumps, gold bumps, copper bumps, copper posts, copper pillars, or the like. The connectors 105′may be formed on and electrically connected to the conductive pads (not shown) of the die 106. For example, a passivation layer (not shown) may be formed to cover portions of the conductive pads and expose another portions of the conductive pads and the connectors 105′ are formed on the conductive pads exposed by the passivation layer.

The connectors 105′ are connected to the conductive layers 12 exposed by the protection layer 15 through a plurality of conductive bumps 30. In other words, the die 106 is electrically connected to the substrate 100. In some embodiments, the conductive bumps 18 are solder bumps, silver balls, copper balls, or any other suitable metallic balls. An underfill layer 32 fills the space between the die 106 and the substrate 100, so as to protect the connectors 105′ and the conductive bumps 30.

In light of the foregoing, the first conductive terminal is formed to have a larger area than the second conductive terminal, and the first conductive terminal is overlapped with the die in a direction perpendicular to the surface of the substrate. With such configuration, the heat originated from the die may be dissipated through the substrate and the first and second conductive terminals disposed thereon in a faster rate. As a result, the heat dissipation performance of the package structure may be greatly improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A package structure, comprising:
a substrate having a first surface and a second surface opposite to each other;
a die, electrically coupled to the substrate;
an encapsulant, disposed over the first surface of the substrate to encapsulate the die;
at least one first conductive terminal and at least one second conductive terminal disposed on the second surface of the substrate, wherein the at least one second conductive terminal is electrically connected to the die through the substrate, the at least one first conductive terminal is overlapped with the die in a direction perpendicular to the second surface of the substrate, and a first area of the at least one first conductive terminal is larger than a second area of the at least one second conductive terminal.

2. The package structure of claim 1, wherein a ratio of the first area to the second area is larger than two.

3. The package structure of claim 1, wherein the at least one first conductive terminal comprises a solder paste and the at least one second conductive terminal comprises a solder ball.

4. The package structure of claim 1, wherein a shape of the at least one first conductive terminal is square or rectangular in a bottom view and a shape of the at least one second conductive terminal is circular or elliptical in a bottom view.

5. The package structure of claim 1, wherein the at least one first conductive terminal is electrically connected to the die through the substrate, and is a power connector, a ground connector or a combination thereof.

6. The package structure of claim 1, wherein the die is electrically coupled to the substrate through a conductive wire or a conductive bump.

7. The package structure of claim 1, wherein the substrate comprises a die region on which the die is disposed and a peripheral region surrounding the die region, the at least one first conductive terminal is located within the die region of the substrate, and the at least one second conductive terminal is located within the peripheral region of the substrate.

8. The package structure of claim 1, wherein the at least one first conductive terminal comprises a plurality of first conductive terminals and the at least one second conductive terminal comprises a plurality of second conductive terminals, a first spacing between two adjacent first conductive terminals is equal to a second spacing between two adjacent second conductive terminals.

9. The package structure of claim 8, wherein the substrate further comprises a plurality of heat dissipation through vias embedded therein, and each of the heat dissipation through vias is vertically aligned with an associated one of the first conductive terminals.

10. The package structure of claim 8, wherein at least two of the first conductive terminals have different shapes and sizes.

11. A manufacturing method of a package structure, comprising:
providing a substrate having a first surface and a second surface opposite to each other, wherein the substrate has a die region and a peripheral region surrounding the die region;
mounting a die on the first surface within the die region of the substrate;
forming an encapsulant over the first surface of the substrate to encapsulate the die;
forming at least one first conductive terminal on the second surface within the die region of the substrate such that the at least one first conductive terminal is overlapped with the die in a direction perpendicular to the second surface of the substrate; and
forming at least one second conductive terminal on the second surface within the peripheral region of the substrate, wherein the at least one first conductive terminal and the at least one second conductive terminal are electrically connected to the die through the substrate, and a first area of the at least one first conductive terminal is larger than a second area of the at least one second conductive terminal.

12. The method of claim 11, wherein the at least one first conductive terminal is formed by a solder paste printing process and the at least one second conductive terminal is formed by a solder ball placement process.

13. The method of claim 11, wherein the substrate comprises a plurality of first conductive pads and a plurality of second conductive pads surrounding the first conductive pads, the at least one first conductive terminal is formed on and in physical contact with the first conductive pads, and the at least one second conductive terminal is formed on and in physical contact with the second conductive pads.

14. The method of claim 11, wherein a ratio of the first area to the second area is larger than two.

15. The method of claim 11, wherein a shape of the at least one first conductive terminal is square or rectangular in a bottom view and a shape of the at least one second conductive terminal is circular or elliptical in a bottom view.

16. The method of claim 11, wherein the at least one first conductive terminal is a power connector, a ground connector, or a combination thereof.

17. The method of claim 11, wherein the at least one first conductive terminal comprises a plurality of first conductive terminals and the at least one second conductive terminal comprises a plurality of second conductive terminals, and a first spacing between two adjacent first conductive terminals is equal to a second spacing between two adjacent second conductive terminals.

18. The method of claim 17, wherein all of the first conductive terminals have the same shape and size.

19. The method of claim 17, wherein at least two of the first conductive terminals have different shapes and sizes.

20. The method of claim 11, wherein the step of forming the at least one first conductive terminal is performed before the step of forming the at least one second conductive terminal.
